(19) United States
(12) Patent Application Publication
(10) Pub. No.: US 2019/0051540 A1
(43) Pub. Date: Feb. 14, 2019

(54) SYSTEMS AND METHODS FOR PLASMA-LESS DE-HALOGENATION

(71) Applicant: Lam Research Corporation, Fremont, CA (US)

(72) Inventors: Ji Zhu, Castro Valley, CA (US); Jatinder Kumar, Fremont, CA (US); Mark Kawaguchi, San Carlos, CA (US); lvelin Angelov, San Jose, CA (US); Serge Kosche, San Francisco, CA (US)

(21) Appl. No.: 15/671,926

(22) Filed: Aug. 8, 2017

(51) Int. Cl. H01L 21/67; H01L 21/02

(52) U.S. Cl. CPC H01L 21/67023; H01L 21/02082; H01L 21/02068

(57) ABSTRACT

A substrate processing system to remove residual halogen species from a substrate includes a processing chamber and a substrate support arranged in the processing chamber to support a substrate. The substrate includes residual halogen species. A heater heats the substrate to a temperature in a predetermined temperature range from 100° C. to 700° C. during a processing period. A chamber pressure controller controls pressure inside the processing chamber in a predetermined pressure range greater than 10 Torr and less than 800 Torr during the processing period. A vapor generator supplies water vapor at least one of in the processing chamber or to the processing chamber during the processing period.

### FIELD

The present disclosure relates to substrate processing systems and methods, and more particularly to systems and methods for plasma-less de-halogenation of substrates.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to deposit, etch or treat film on a substrate such as a semiconductor wafer. The substrate processing systems typically include a processing chamber, a gas distribution device such as a showerhead and a substrate support. During processing, the substrate is arranged on the substrate support. Different gas mixtures may be introduced into the processing chamber and plasma may be used during some processes to activate chemical reactions.

Current etch treatments rely on chemicals containing halogen species such as fluorine (F), chlorine (CI), bromine (Br) or iodine (I). After the etch treatment, high levels of halogen species remain on a surface of the substrate (for example, 1E15 atoms/cm²). Unless removed, residual halogens cause downstream processing issues such as reduced device electrical performance and moisture condensation from air, which can lead to pattern collapse, particle issues, and other problems.

As feature sizes continue to decrease, removal processes for residual halogens need to meet increasingly stringent material loss requirements of less than 1 monolayer. Current technologies have difficulty meeting this requirement while maintaining sufficient residual halogen removal. Fluorine is typically the most difficult halogen species to remove due to the strong silicon-fluorine (Si—F) bond. Many current techniques don't address fluorine removal adequately.

Plasma treatment may be used to remove residual halogens. For example, exposure to plasma using a plasma gas such as molecular oxygen (O₂), molecular hydrogen and carbon dioxide (H₂/CO₂), water (H₂O) and/or molecular nitrogen and molecular hydrogen (N₂/H₂) may be used. Although these plasma treatments are effective in removing CI, Br or I, they are generally ineffective in removing F from the substrate surface. For example, F removal via H₂O-based plasma is limited to 30-40%. The plasma also causes material loss through oxidation via oxygen in the plasma. Oxidation can also occur when using N₂/H₂ plasma due to H scavenging oxygen from ceramic or quartz components in the processing chamber. Typical oxidation levels are 10-20 Angstroms (A), which exceeds the requirement of <1 monolayer material loss.

Plasma with RF bias is effective in removing halogens including F from line of sight exposed surfaces, but causes increased oxidation and material loss. It is also difficult for biased plasma to penetrate into recessed features such as a 3D NAND structures.

Deionized water (DIW) is effective in removing halogens, but the efficiency in removing fluorine is still limited to ˜70%. However, as technology progresses, high aspect ratio (HAR) structures on the substrate are increasingly sensitive to collapse and damage during drying after DIW exposure.

High temperature annealing may also be used. Residual halogens can also be removed from the substrates when the substrates are exposed to high temperature (e.g. temperature >800° C.). This temperature is not compatible with epitaxial grown films such as silicon (Si), silicon germanium (SiGe), silicon phosphide (SiP), etc. Exposure to high temperature annealing also causes issues such as film property changes, atomic diffusion, dopant profile shift, etc.

### SUMMARY

A substrate processing system to remove residual halogen species from a substrate includes a processing chamber and a substrate support arranged in the processing chamber to support a substrate. The substrate includes residual halogen species. A heater heats the substrate to a temperature in a predetermined temperature range from 100° C. to 700° C. during a processing period. A chamber pressure controller controls pressure inside the processing chamber in a predetermined pressure range greater than 10 Torr and less than 800 Torr during the processing period. A vapor generator supplies water vapor at least one of in the processing chamber or to the processing chamber during the processing period.

In other features, the substrate includes an epitaxial film and the predetermined temperature range is from 400° C. to 550° C. during the processing period. The substrate includes a material selected from a group consisting of silicon (Si), silicon germanium (SiGe), silicon phosphide (SiP), and silicon carbide (SiC). The predetermined temperature range is from 550° C. to 700° C. during the processing period. The predetermined pressure range is from 50 Torr to 500 Torr.

In other features, the predetermined pressure range is from 100 Torr to 300 Torr. Removal of residual halogen species is performed without plasma. The processing chamber comprises a load lock. The processing chamber comprises an inductively coupled plasma (ICP) chamber.

In other features, the heater is integrated into the substrate support. The heater is selected from a group consisting of an infrared (IR) heater and a light emitting diode (LED) heater. The vapor generator generates the water vapor in the processing chamber during the processing period using a gas mixture including one or more gases and a metal catalyst.

In other features, the vapor generator generates the water vapor in the processing chamber. A conduit connects the vapor generator to the processing chamber. A heater heats the conduit to a temperature greater than 100° C.

In other features, the predetermined temperature range is from 400° C. to 700° C. during the processing period.

A substrate processing tool includes the substrate processing system. An etching chamber etches the substrate using a halogen species. A robot transfers the substrate from the etching chamber to the substrate processing system.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a graph illustrating an example of fluorine levels on a substrate surface as a function of vapor pressure according to the present disclosure;

FIG. 2 is a functional block diagram of an example of an ICP chamber that performs etching or residue removal and plasma-less de-halogenation according to the present disclosure;

FIGS. 3-4 are functional block diagrams of examples of processing chambers that perform plasma-less de-halogenation according to the present disclosure;

FIG. 5 is a functional block diagram of an example of a processing chamber that performs plasma processing such as etching or residue removal using a remote plasma source and performs plasma-less de-halogenation according to the present disclosure;

FIG. 6 is a functional block diagram of an example of a substrate processing tool that includes at least one processing chamber that performs plasma-less de-halogenation according to the present disclosure; and

FIG. 7 is a flowchart illustrating an example of a method for performing plasma-less de-halogenation according to the present disclosure.

In the drawings, reference numbers may be reused to identify similar and/or identical elements.

### DETAILED DESCRIPTION

Systems and methods according to the present disclosure are used to remove residual halogen species from a substrate. The systems and methods described herein use water vapor at high pressure and high temperature to remove residual halogen species, including F, CI, Br and/or I. In some examples, the water vapor is generated using deionized water (DIW). The systems and methods expose the substrate to water vapor at pressures greater than 10 Torr and at an elevated temperature (for example greater than 300° C.) for a predetermined period to allow the water vapor to react with residual halogen species on a surface of the substrate.

The water vapor is subsequently evacuated from the chamber. The substrate is removed from the chamber after the substrate cools down to a temperature greater than 100° C. to prevent potential residual water condensation. Systems and methods according to the present disclosure provide a high level (>90%) of fluorine removal, which is comparable to wet clean methods while causing little material loss.

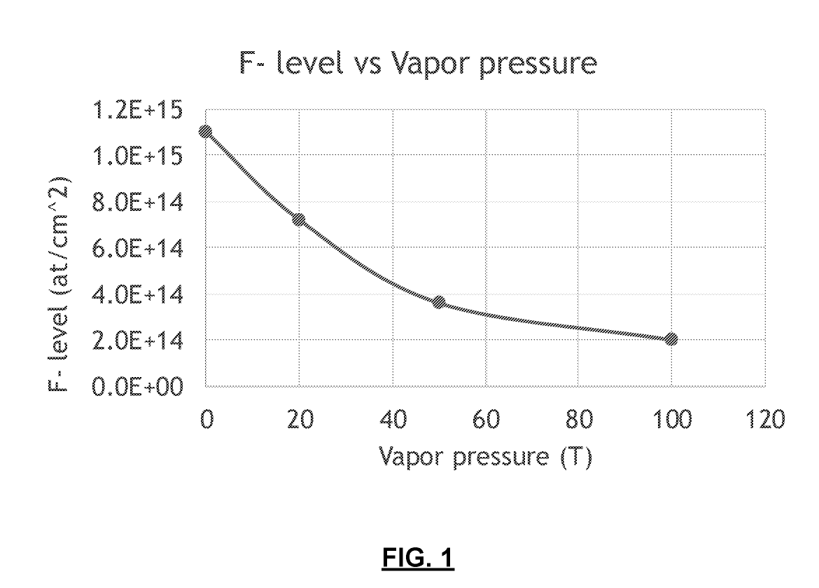

Referring now to FIG. 1, residual fluorine levels on the substrate are shown as a function of water vapor pressure. As can be seen, the residual fluorine levels on the substrate decrease as a function of water vapor pressure. Systems and methods for plasma-less dehalogenation using water vapor according to the present disclosure can be performed in the same chamber as a prior process such as etching or residue removal, in a separate chamber and/or in a load lock.

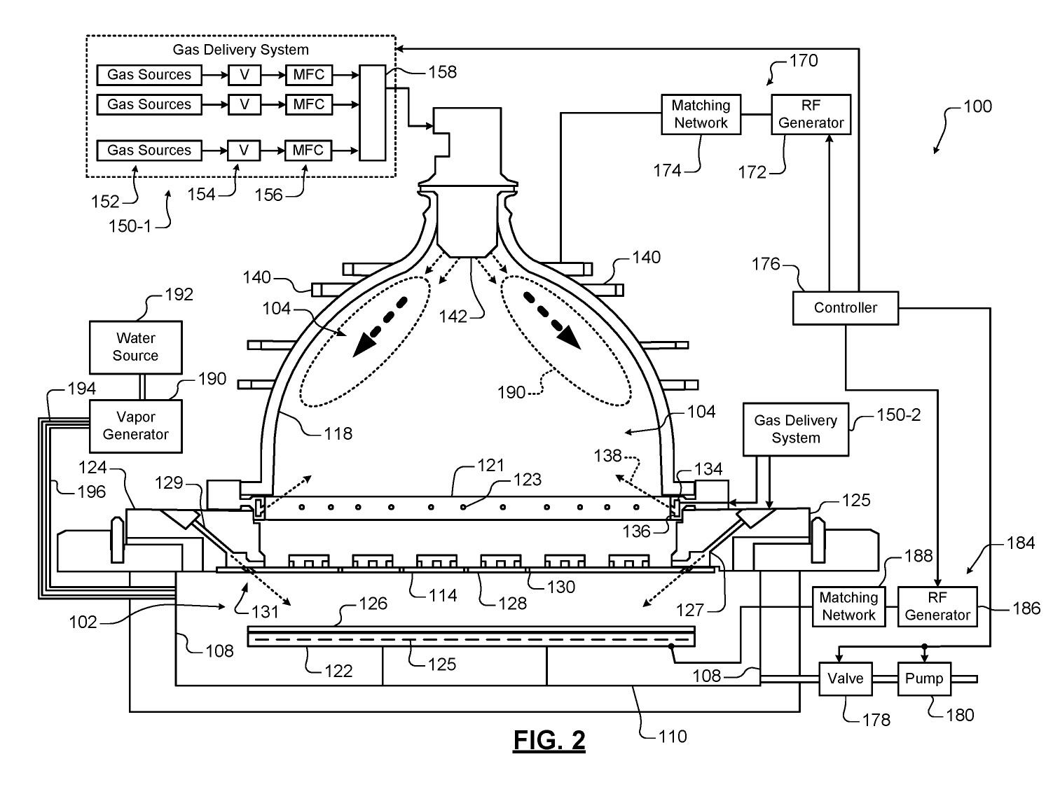

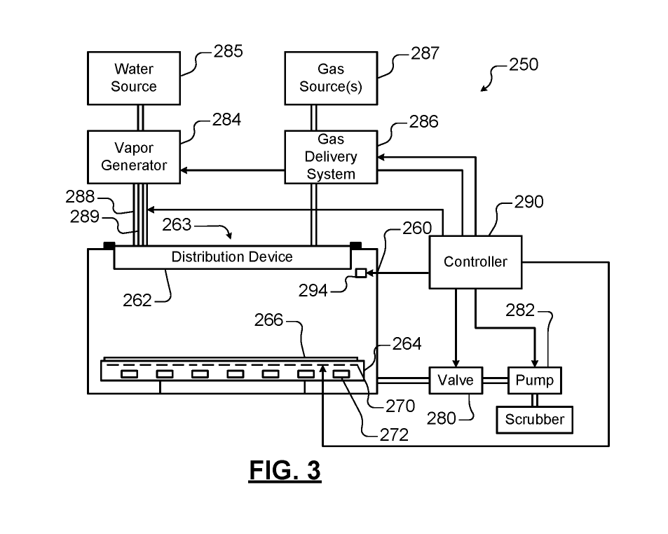

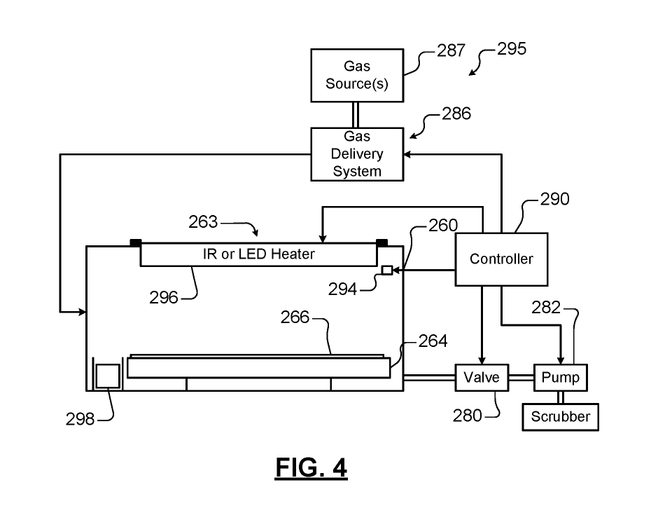

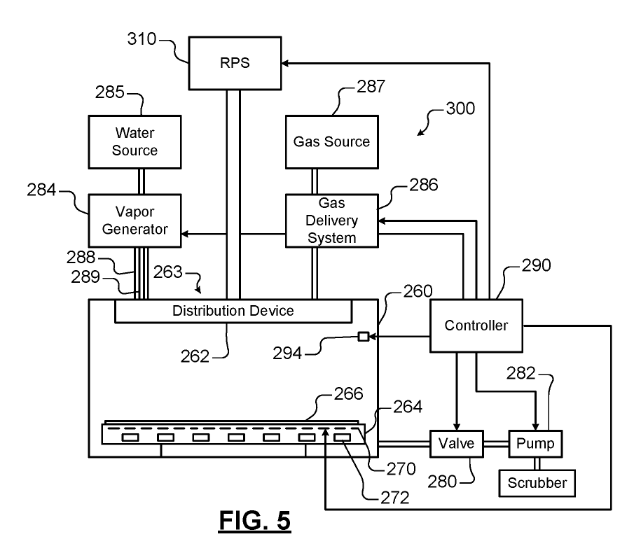

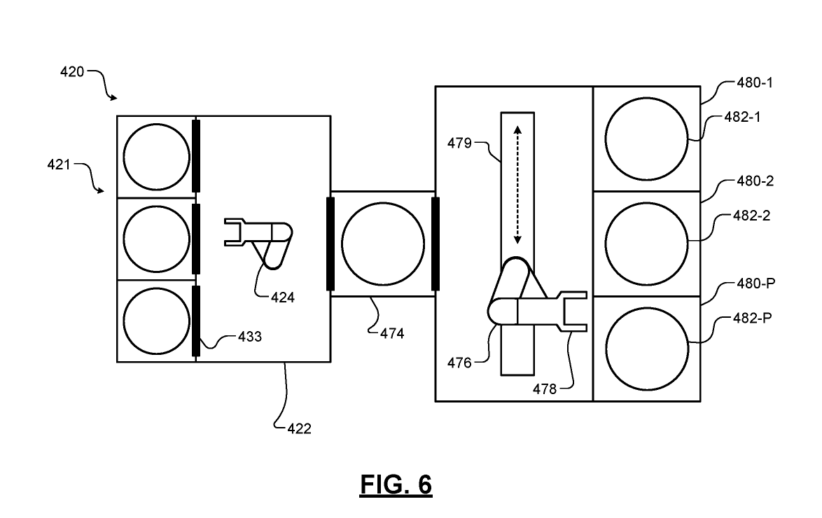

For example in FIG. 2, plasma-less dehalogenation is implemented in an inductively coupled plasma (ICP) chamber that also performed etching or residue removal. In FIGS. 3-4, plasma-less dehalogenation is implemented in standalone chambers. In FIG. 5, plasma-less dehalogenation is implemented in a chamber that also performs etching or residue removal using a remote plasma source. In FIG. 6, a tool is shown that includes multiple chambers. At least one chamber that is capable of plasma-less dehalogenation and another chamber is capable of etching and/or residue removal.

Referring now to FIG. 2, an example of a substrate processing chamber 100 for performing both etching and plasma-less dehalogenation of a substrate according to the present disclosure is shown. While a specific substrate processing chamber is shown and described, the methods described herein may be implemented on other types of substrate processing systems.

The substrate processing chamber 100 includes a lower chamber region 102 and an upper chamber region 104. The lower chamber region 102 is defined by chamber sidewall surfaces 108, a chamber bottom surface 110 and a lower surface of a gas distribution device 114.

The upper chamber region 104 is defined by an upper surface of the gas distribution device 114 and an inner surface of a dome 118. In some examples, the dome 118 rests on a first annular support 121. In some examples, the first annular support 121 includes one or more spaced holes 123 for delivering process gas to the upper chamber region 104, as will be described further below. In some examples, the process gas is delivered by the one or more spaced holes 123 in an upward direction at an acute angle relative to a plane including the gas distribution device 114, although other angles/directions may be used. In some examples, a gas flow channel 134 in the first annular support 121 supplies gas to the one or more spaced holes 123.

The first annular support 121 may rest on a second annular support 124 that defines one or more spaced holes 127 for delivering process gas from a gas flow channel 129 to the lower chamber region 102. In some examples, holes 131 in the gas distribution device 114 align with the holes 127. In other examples, the gas distribution device 114 has a smaller diameter and the holes 131 are not needed. In some examples, the process gas is delivered by the one or more spaced holes 127 in a downward direction towards the substrate at an acute angle relative to the plane including the gas distribution device 114, although other angles/directions may be used.

In other examples, the upper chamber region 104 is cylindrical with a flat top surface and one or more flat inductive coils may be used. In still other examples, a single chamber may be used with a spacer located between a showerhead and the substrate support.

A substrate support 122 is arranged in the lower chamber region 104. In some examples, the substrate support 122 includes an electrostatic chuck (ESC), although other types of substrate supports can be used. A substrate 126 is arranged on an upper surface of the substrate support 122 during etching. In some examples, a temperature of the substrate 126 may be controlled by a heater plate 125, an optional cooling plate with fluid channels and one or more sensors (not shown); although any other suitable substrate support temperature control system may be used.

In some examples, the gas distribution device 114 includes a showerhead (for example, a plate 128 having a plurality of spaced holes 130). The plurality of spaced holes 130 extend from the upper surface of the plate 128 to the lower surface of the plate 128. In some examples, the spaced holes 130 have a diameter in a range from 0.4″ to 0.75″ and the showerhead is made of a conducting material such as aluminum or a non-conductive material such as ceramic with an embedded electrode made of a conducting material.

One or more inductive coils 140 are arranged around an outer portion of the dome 118. When energized, the one or more inductive coils 140 create an electromagnetic field inside of the dome 118. In some examples, an upper coil and a lower coil are used. A gas injector 142 injects one or more gas mixtures from a gas delivery system 150-1.

In some examples, a gas delivery system 150-1 includes one or more gas sources 152, one or more valves 154, one or more mass flow controllers (MFCs) 156, and a mixing manifold 158, although other types of gas delivery systems may be used. A gas splitter (not shown) may be used to vary flow rates of a gas mixture. Another gas delivery system 150-2 may be used to supply an etch gas or an etch gas mixture to the gas flow channels 129 and/or 134 (in addition to or instead of etch gas from the gas injector 142).

In some examples, the gas injector 142 includes a center injection location that directs gas in a downward direction and one or more side injection locations that inject gas at an angle with respect to the downward direction. In some examples, the gas delivery system 150-1 delivers a first portion of the gas mixture at a first flow rate to the center injection location and a second portion of the gas mixture at a second flow rate to the side injection location(s) of the gas injector 142. In other examples, different gas mixtures are delivered by the gas injector 142. In some examples, the gas delivery system 150-1 delivers tuning gas to the gas flow channels 129 and 134 and/or to other locations in the processing chamber as will be described below.

A plasma generator 170 may be used to generate RF power that is output to the one or more inductive coils 140. Plasma 190 is generated in the upper chamber region 104. In some examples, the plasma generator 170 includes an RF generator 172 and a matching network 174. The matching network 174 matches an impedance of the RF generator 172 to the impedance of the one or more inductive coils 140. In some examples, the gas distribution device 114 is connected to a reference potential such as ground. A valve 178 and a pump 180 may be used to control pressure inside of the lower and upper chamber regions 102, 104 and to evacuate reactants.

During plasma-less de-halogenation, a vapor generator 190 receives water from a water source 192 and generates water vapor. Lines 194 from the vapor generator 190 to the chamber (for example the lower chamber region 102) may be heated by a heater 196 to a temperature greater than 100° C. to prevent condensation. While the water vapor is delivered using the vapor generator 190 with the lines 194 that are heated in this example, vapor delivery can be generated in situ by combining a gas mixture such as molecular hydrogen and molecular oxygen (H₂/O₂) and one or more metal catalysts such as platinum (Pt), palladium (Pd), nickel (Ni), etc.

A controller 176 communicates with the gas delivery systems 150-1 and 150-2, the valve 178, the pump 180, the plasma generator 170 and the vapor generator 190 to control flow of process gas, purge gas, RF plasma and chamber pressure during etching. The controller 176 also controls substrate temperature and vapor delivery during plasma-less dehalogenation. In some examples, plasma is sustained inside the dome 118 during etching by the one or more inductive coils 140. During etching, one or more gas mixtures are introduced from a top portion of the chamber using the gas injector 142 (and/or the spaced holes 123) and plasma is confined within the dome 118 using the gas distribution device 114.

An RF bias generator 184 may be provided and includes an RF generator 186 and a matching network 188. The RF bias can be used to create plasma between the gas distribution device 114 and the substrate support or to create a self-bias on the substrate 126 to attract ions. The controller 176 may be used to control the RF bias.

In use, the substrates are etched or residue is removed using ICP plasma with a plasma gas mixture including a halogen species. After etching, residual halogens are removed using water vapor as described herein.

Referring now to FIGS. 3-4, standalone processing chambers for performing plasma-less de-halogenation are shown. In FIG. 3, a processing system 250 includes a chamber 260 including a gas distribution device 262. In some examples, the distribution device 262 is integrated with a lid 263 of the chamber 260. In some examples, the gas distribution device 262 includes a showerhead or platen including a plurality of through holes, although other gas distribution devices can be used. The processing system 250 further includes a substrate support 264 such as a pedestal or an electrostatic chuck (ESC) to support a substrate 266. The substrate support 264 includes a heater 270 such as a resistive heater. The substrate support 264 may further include channels 272 for receiving heating or cooling fluid to control the temperature of the substrate support 264.

The processing system 250 further includes a valve 280 and a pump 282 to control a pressure inside the chamber 260 and/or to evacuate reactants from the chamber 260. The processing system 250 further includes a vapor generator 284 that supplies water vapor from a water source 285. The vapor generator 284 may include one or more valves and/or flow control devices such as a mass flow controller (not shown). A gas delivery system 286 supplies gases from one or more gas sources 287. A heater 288 may be used to heat lines 289 connecting the vapor generator 284 to the chamber 260 to a temperature above 100° C.

One or more sensors 294 may be used to sense temperature and/or pressure of the substrate support and/or at other locations inside the chamber 260. A controller 290 controls the temperature of the substrate support 264, the pressure in the chamber 260, supply of the water vapor from the vapor generator 284, and supply of gases from the gas delivery system 286. The controller 290 may further control evacuation of reactants from the chamber 260. The gas delivery system 286 may be used to supply a gas mixture during water vapor generation and/or one or more inert gases after plasma-less de-halogenation as described herein.

In FIG. 4, a processing chamber 295 includes a heater 296 including an infrared (IR) heater or light emitting diode (LED) array that can be used to heat the substrate. The position of the IR heater or LED array can be either above or below the wafer surface. The water vapor is generated in situ using a process gas mixture and a metal catalyst 298. For example, a gas mixture such as hydrogen and oxygen (H₂/O₂) and one or more metal catalysts such as platinum (Pt), palladium (Pd), nickel (Ni), etc can be used.

Referring now to FIG. 5, another processing chamber 300 that is similar to the chamber shown in FIG. 3 is presented. The processing chamber 300 further includes a remote plasma source (RPS) 310 that generates remote plasma, which may be used for substrate processing such as etching or residue removal. After the process using the remote plasma is complete, water vapor can be used to remove halogen species from the substrate without moving the substrate from the processing chamber 300.

Referring now to FIG. 6, a tool 420 including multiple processing chamber is shown. A substrate enters the tool 420 from a cassette loaded through a pod 421, such as the front opening unified pod (FOUP). A robot 424 includes one or more end effectors to handle the substrates. A pressure of the robot 424 is typically at atmospheric pressure. The robot 424 moves the substrates from the cassette to one port of a transfer chamber 474. The transfer chamber 474 pumps pressure therein to an appropriate level.

Another port to the transfer chamber 474 opens and a robot 476 with one or more end effectors 478 delivers the substrate to a selected one of a plurality of processing chambers 480-1, 480-2, . . . , and 480-P (collectively processing chambers 480), where P is an integer greater than one. The robot 476 may move along a track 479. The robot 476 delivers the substrate onto one of a plurality of pedestals 482-1, 482-2, . . . , and 482-P corresponding to the selected one of the processing chambers 480. In some examples, at least one of the processing chambers 480 performs plasma-less dehalogenation and at least another one of the processing chambers 480 performs etching or residue removal using plasma and a plasma gas mixture including a halogen species. In some examples, plasma-less de-halogenation may be performed in the transfer chamber 474 after processing.

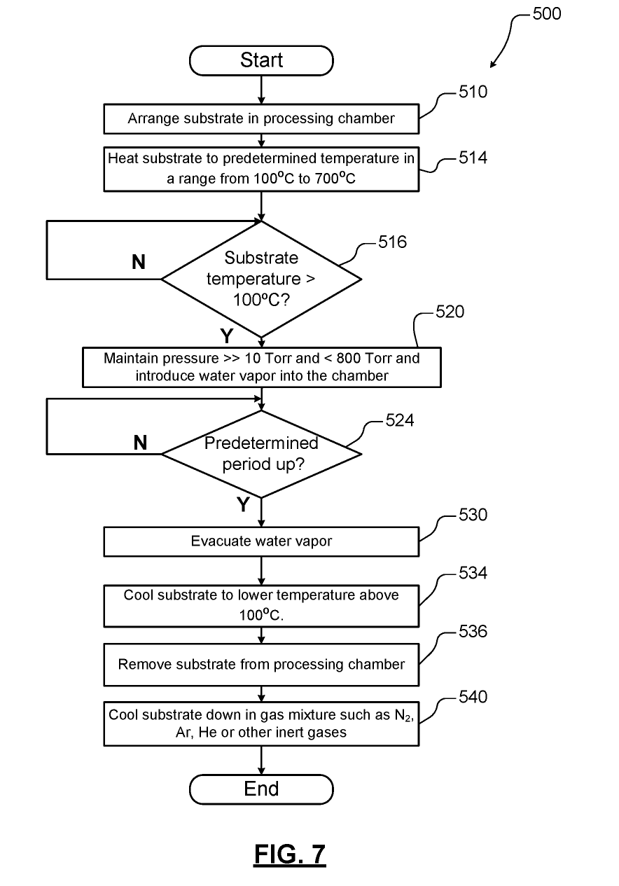

Referring now to FIG. 7, a method 500 for plasma-less de-halogenation is shown. At 510, the substrate is arranged in a processing chamber. As described above, the processing chamber can include a standalone plasma-less de-halogenation chamber or can be combined with a chamber performing other functions such as etching and/or residue removal.

At 514, the substrate is heated to a predetermined temperature. In some examples, the predetermined temperature is in a temperature range from 100° C. to 700° C. In other examples, the predetermined temperature is in a temperature range from 400° C. to 700° C. In other examples, the predetermined temperature is in a temperature range from 550° C. to 700° C.

While a heated pedestal is shown, alternative heating methods such as an infrared (IR) lamp or light emitting diode (LED) heaters can be used. In some examples, a temperature in a range from 400° C. to 550° C. for epitaxial films, such as silicon (Si), silicon germanium (SiGe), silicon phosphide (SiP), silicon carbide (SiC) and similar films where deposition temperature is normally less than or equal to 550° C. For other types of films, a temperature range from 550° C. to 700° C. can be used for removal efficiency and throughput enhancement.

At 516, the method determines whether the substrate temperature is greater than or equal to a predetermined temperature such as 100° C., 200° C., or other predetermined temperatures that are greater than 100°. At 520, water vapor is introduced into the chamber and pressure is maintained at a predetermined pressure.

In some examples, the pressure is maintained in a predetermined pressure range that is greater than 10 Torr and less than 800 Torr during plasma-less de-halogenation. In some examples, the pressure is maintained in a predetermined pressure range from 50 Torr to 500 Torr during plasma-less de-halogenation. In some examples, a pressure is maintained in a predetermined pressure range from 100 Torr to 300 Torr during plasma-less de-halogenation.

At 524, the method determines whether the predetermined treatment period is up. When 524 is true, the water vapor is evacuated at 530. For example, the water vapor is removed either via vacuum pumping or purging.

At 534, the substrate is cooled to a lower temperature that is above 100° C. At 536, the substrate is removed from the processing chamber. In some examples, the substrate is cooled down and a gas mixture including molecular nitrogen, argon, helium and/or other inert gases is supplied.

The systems and methods according to the present disclosure address fluorine removal issues, which are ineffectively addressed by other treatments. Water vapor is used due to its favorable energetics. To address oxidation issues, a plasma-less water vapor is used to remove halogen. Without plasma, thermal oxidation at the effective temperature (for example, 500° C. in water vapor) is measured to be low, for example less than 1 A on amorphous-Si (a-Si) surface. As compared to DIW rinse methods, the substrate is always kept at a temperature greater than 100° C. to prevent condensation on the substrate. There is no pattern collapse risk with water vapor at high temperature.

In some examples, the plasma-less dehalogenation is performed in a tool that also performs etching and/or residue removal to avoid condensation-induced post-etch pattern collapse. For example, the substrate a shallow trench isolation (STI) tool processes a substrate through an STI etch chamber, an ICP chamber such as the chamber shown above in FIG. 2 for residue removal, and a plasma-less de-halogenation chamber. This sequence has the potential of eliminating wet clean entirely. In some examples, the plasma-less dehalogenation chamber does not run etch processes to avoid halogen residue accumulation in the chamber. In still other examples, the plasma-less de-halogenation chamber is implemented in a load lock.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor substrate or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, substrate transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a substrate.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor substrates.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of substrates to and from tool locations and/or load ports in a semiconductor manufacturing factory.

What is claimed is:

1. A substrate processing system to remove residual halogen species from a substrate comprising:
a processing chamber;
a substrate support arranged in the processing chamber to support a substrate,
wherein the substrate includes residual halogen species, and
a heater to heat the substrate to a temperature in a predetermined temperature range from 100° C. to 700° C. during a processing period;
a chamber pressure controller to control pressure inside the processing chamber in a predetermined pressure range greater than 10 Torr and less than 800 Torr during the processing period; and
a vapor generator to supply water vapor at least one of in the processing chamber or to the processing chamber during the processing period.

2. The substrate processing system of claim 1, wherein the substrate includes an epitaxial film and the predetermined temperature range is from 400° C. to 550° C. during the processing period.

3. The substrate processing system of claim 1, wherein the substrate includes a material selected from a group consisting of silicon, silicon germanium (SiGe), silicon phosphide (SiP), and silicon carbide (SiC).

4. The substrate processing system of claim 1, wherein the predetermined temperature range is from 550° C. to 700° C. during the processing period.

5. The substrate processing system of claim 1, wherein the predetermined pressure range is from 50 Torr to 500 Torr.

6. The substrate processing system of claim 1, wherein the predetermined pressure range is from 100 Torr to 300 Torr.

7. The substrate processing system of claim 1, wherein removal of residual halogen species is performed without plasma.

8. The substrate processing system of claim 1, wherein the processing chamber comprises a load lock.

9. The substrate processing system of claim 1, wherein the processing chamber comprises an inductively coupled plasma (ICP) chamber.

10. The substrate processing system of claim 1, wherein the heater is integrated into the substrate support.

11. The substrate processing system of claim 1, wherein the heater is selected from a group consisting of an infrared (IR) heater and a light emitting diode (LED) heater.

12. The substrate processing system of claim 1, wherein the vapor generator generates the water vapor in the processing chamber during the processing period using a gas mixture including one or more gases and a metal catalyst.

13. The substrate processing system of claim 1, wherein the vapor generator generates the water vapor in the processing chamber and further comprising:
a conduit connecting the vapor generator to the processing chamber; and
a heater to heat the conduit to a temperature greater than 100° C.

14. A substrate processing tool comprising:
the substrate processing system of claim 1;
an etching chamber that etches the substrate using a halogen species; and
a robot to transfer the substrate from the etching chamber to the substrate processing system.

15. The substrate processing system of claim 1, wherein the predetermined temperature range is from 400° C. to 700° C. during the processing period.
